(19) United States
(12) Patent Application Publication
(10) Pub. No.: US 2016/0262291 A1
(43) Pub. Date: Sep. 8, 2016

(54) GASKET HAVING TWO REGIONS OF FOAM DENSITIES

(71) Applicant: Laird Technologies, Inc., Earth City, MO (US)

(72) Inventors: John Michael Tucker, St. Louis, MO (US); Frank Joseph Gibilterra, Ferguson, MO (US)

(21) Appl. No.: 14/640,438

(22) Filed: Mar. 6, 2015

(51) Int. Cl. H05K 9/00

(52) U.S. Cl. CPC H05K 9/0015

(57) ABSTRACT

Fabric-over-foam (and foil-over-foam) electromagnetic interference attenuating gaskets having a body of indefinite length are disclosed, the gaskets having a foam core surrounded by conductive fabric, where the foam core possesses at least two distinct regions of foam density. Methods of manufacturing the gaskets are also disclosed.

### FIELD OF THE INVENTION

The disclosure relates, generally, to fabric over foam or film over foam (collectively, FOF) contacts and gaskets, including those that provide attenuation of electromagnetic interference (EMI), which can have an undesired effect on electronic devices, among other harms.

### BACKGROUND

The statements in this section merely provide background information related to this disclosure and do not necessarily constitute prior art.

During normal operation, electronic equipment can generate undesirable electromagnetic energy that can interfere with the operation of proximately located electronic equipment due to electromagnetic interference (EMI) transmission by radiation and conduction. The electromagnetic energy can be of a wide range of wavelengths and frequencies. To reduce the problems associated with EMI, sources of undesirable electromagnetic energy may be shielded and electrically grounded. Shielding can be designed to prevent both ingress and egress of electromagnetic energy relative to a housing or other enclosure in which the electronic equipment is disposed. Since such enclosures often include gaps or seams between adjacent access panels and around doors and connectors, effective shielding can be difficult to attain because the gaps in the enclosure permit transference of EMI therethrough. Further, in the case of electrically conductive metal enclosures, these gaps can inhibit the beneficial Faraday Cage Effect by forming discontinuities in the conductivity of the enclosure which compromise the efficiency of the ground conduction path through the enclosure. Moreover, by presenting an electrical conductivity level at the gaps that is significantly different from that of the enclosure generally, the gaps can act as a slot antennae, resulting in the enclosure itself becoming a secondary source of EMI.

EMI gaskets have been developed for use in gaps and around doors to provide a degree of EMI shielding while permitting operation of enclosure doors and access panels and fitting of connectors. To shield EMI effectively, the gasket should be capable of absorbing or reflecting EMI as well as establishing a continuous electrically conductive path across the gap in which the gasket is disposed. These gaskets can also be used for maintaining electrical continuity across a structure and for excluding from the interior of the device such contaminates as moisture and dust. Once installed, the gaskets essentially close or seal any interface gaps and establish a continuous electrically-conductive path thereacross by conforming under an applied pressure to irregularities between the surfaces. Accordingly, gaskets intended for EMI shielding applications are specified to be of a construction that not only provides electrical surface conductivity even while under compression, but which also has a resiliency allowing the gaskets to conform to the size of the gap.

As used herein, the term “EMI” should be considered to generally include and refer to EMI emissions and RFI emissions, and the term “electromagnetic” should be considered to generally include and refer to electromagnetic and radio frequency from external sources and internal sources. Accordingly, the term shielding (as used herein) generally includes and refers to EMI shielding and RFI shielding, for example, to prevent (or at least reduce) ingress and egress of EMI and RFI relative to a housing or other enclosure in which electronic equipment is disposed.

### SUMMARY OF THE DISCLOSURE

FOF EMI gaskets are disclosed. The gasket of the disclosure may have a body of indefinite length. In an exemplary embodiment, the gasket may be compressible between two substrates, including for example substrates with substantially planar surfaces, where one substrate may be a printed circuit board (PCB) onto which the gasket has been mounted.

The gasket may be a foam core surrounded by conductive fabric, where the foam core possesses at least two distinct regions of foam density. This gasket may be a plurality of foam cores, each having a distinct foam density, where the foam cores are adhered together, and together wrapped in a conductive fabric, or alternatively wrapped in conductive film or other suitable flexible wrappable conductive material known in the art. The conductive wrap around the foam may be adhered to the foam via any conventional FOF mechanism, including through the use of a pressure sensitive adhesive or a hot melt adhesive. The gasket may include a strip of pressure sensitive adhesive or tape that runs the length of the gasket and is attached to the bottom of the gasket, such that the gasket may be adhered to a surface, such as a PCB. Such adhesive or tape may be conductive such that the PCB may, through the adhesive or tape and the FOF gasket, maintain electrical contact with a second surface that might come into contact with the top of the gasket.

Further aspects and features of the present disclosure will become apparent from the detailed description provided hereinafter, in conjunction with the figures. In addition, one or more aspects of the present disclosure may be implemented individually or in any combination with any one or more of the other aspects of the present disclosure. It should be understood that the detailed description and specific examples, while indicating exemplary embodiments of the present disclosure, are intended for purposes of illustration only and are not intended to limit the scope of this disclosure.

### DESCRIPTION OF THE FIGURES

FIG. 1 shows a cross-sectional view of an embodiment of the gasket of the disclosure, this view illustrating the distinct regions of foam density.

FIG. 2 shows an elevated perspective view of an embodiment of the gasket of the disclosure, this gasket being in an uncompressed at-rest state.

FIG. 3 shows a cross-sectional view of an embodiment of the gasket of the disclosure, this view showing the downward compression force and resulting initial deformation of at least one region of foam density.

FIG. 4 shows various profile views of embodiments of the gasket of the disclosure.

FIG. 5 shows various profile views of embodiments of the gasket of the disclosure.

FIG. 6 shows a force/displacement/resistance graph of embodiments of the gasket of the disclosure seen in FIGS. 1 through 3, for two different samples of the gasket, showing the full test range of the gasket.

FIG. 7 shows a force/displacement/resistance graph, as in FIG. 6, of the gasket of the disclosure, for the two samples of FIG. 6, this graph showing the data for a range more reflective of the typical operating range of the gasket.

### DETAILED DESCRIPTION

The following description of various embodiments is merely exemplary in nature and is in no way intended to limit the invention, its application, or its uses. Variations from the embodiments in this disclosure are thus fully embraced by the spirit and scope of the invention, including all equivalents.

A FOF EMI gasket is disclosed, the gasket having a resilient foam core having at least two distinct regions of foam density. The foam core is wrapped in an electrically conductive layer, and this layer is adhered to the foam core via an adhesive. The gasket is generally of indefinite length, but may be of any suitable length as needed in the end use application. In use, the gasket may have a strip of tape or adhesive or solderable material along its base to allow the gasket to be affixed to a surface, such as a printed circuit board. This strip of material may be conductive. Each gasket has a profile that generally defines the shape of the end face or of any given cross section of the gasket when a complete cut is made perpendicular to the length of the gasket.

The foam core may be constructed of a plurality of independently made strips of foam of varying densities that have been adhered together to form a unified foam core. Where multiple strips are joined to make a unified foam core, these strips may be joined in a variety of manners, including through the use of double sided tape, or through the use of adhesive, including whatever adhesive is used to adhere the conductive layer to the foam core.

In use, the FOF EMI gasket may be compressed in predictable and modifiable ways. The portion of the gasket that includes the foam with the lower density may deflect first when a force is applied to the gasket. Once that first compression has occurred, the second denser region of foam may be compressed upon the application of further force. The shapes and relative sizes and configurations of these regions of varying foam density may be adjusted as needed in the application of the gasket. Generally, the gaskets of the disclosure enable the filling of large gaps in electronic devices without causing a buckling of the gasket, and enable more consistency in the contact area of the gasket to another surface, as compared to some prior art gaskets. As will be seen in the figures, improved control over the force-deflection curve of the gasket may also be seen.

The foam core of the disclosure is a porous material composed of any suitable foam material known in the art in the manufacture to act as a resilient or semi-resilient foam core of FOF EMI gaskets. The foam core may be comprised of open cell foam or closed cell foam, as the end application of the gasket merits. In a non-limiting example, the foam is urethane foam. In an embodiment, the foam core is two lengths of open cell polyurethane foam of different foam densities that have been adhered together via a double sided tape.

The conductive layer of the disclosure may be any suitable electrically-conductive wrap known in the art in the manufacture of FOF EMI gaskets. Non-limiting examples of such layers include nylon ripstop fabrics, mesh fabrics, taffeta fabrics, woven fabrics, non-woven fabrics, or knitted fabrics that have been coated, impregnated, plated, metallized or otherwise treated with electrically conductive material to create a flexible wrappable layer that may be wrapped around a foam core. In addition, a metallized film may be used as an electrically conductive layer. The electrically conductive material may include, by way of non-limiting examples, copper, nickel, silver, palladium, aluminum, tin, alloys and/or combinations thereof. In an embodiment, the conductive layer is a woven fabric that has been coated with an alloy of copper and tin. In another embodiment, the conductive layer is a metal foil of aluminum, copper, tin, or any alloy thereof.

The conductive layer may be adhered to the foam core through the use of any suitable adhesive known in the art in the manufacture of FOF EMI gaskets. Ideally, the adhesive layer should provide good bond strength between the foam core and the electrically conductive layer. The adhesive layer should provide proper shielding effectiveness and bulk resistivity for the FOF EMI gasket application. A non-limiting example of such materials is a solvent based polyester adhesive. In an embodiment, the adhesive further includes flame retardant, such as a halogen free flame retardant.

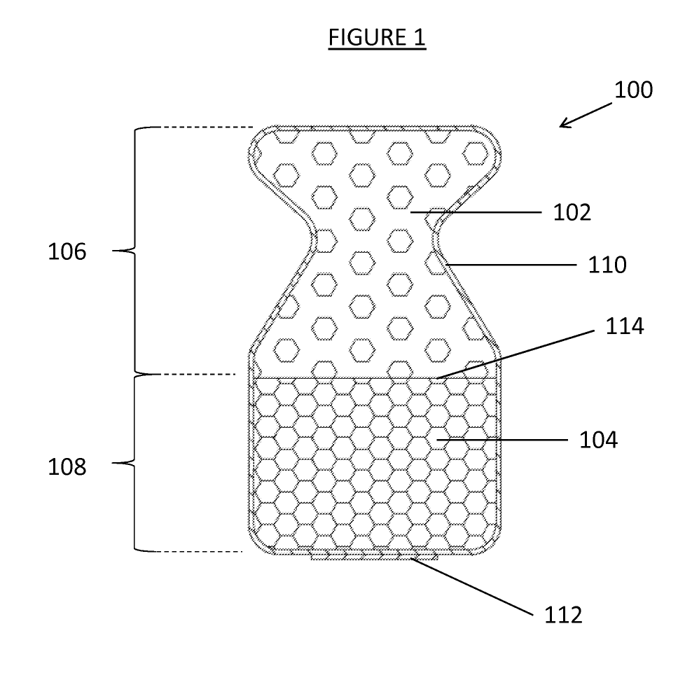

Turning to the figures, FIG. 1 shows a profile of an embodiment of the FOF EMI gasket 100 of the disclosure. In this gasket 100, one may see a first foam 102 having a first foam density, and a second foam 104 having a second foam density. Here, the first foam density and the second foam density are of unequal values. A first foam region 106 includes the first foam 102 and other components of the EMI gasket, as will be described further. Similarly, the second foam region 108 includes the second foam 104 and other gasket components. Both the first foam 102 and the second foam 104 have been adhered to one another and wrapped in an electrically conductive layer 110, such that the wrapping is a complete envelopment of the foam core to provide a complete electrical connection around the gasket 100. At the base of the gasket 100 is an optional adhesive strip 112 for adhering the gasket 100 to a surface, such as a printed circuit board.

Between the two foams 102, 104 is an adhesive 114 that partitions the two foams 102, 104 and provides a seal therebetween, and further provides a division between the first foam region 106 and the second foam region 108. The foam core may be constructed of a plurality of independently made strips of foam of varying densities that have been adhered together to form a unified foam core. In this way, the gasket 100 of the disclosure may have a cross-sectional profile that is the sum of the profiles of the independently made foam strips.

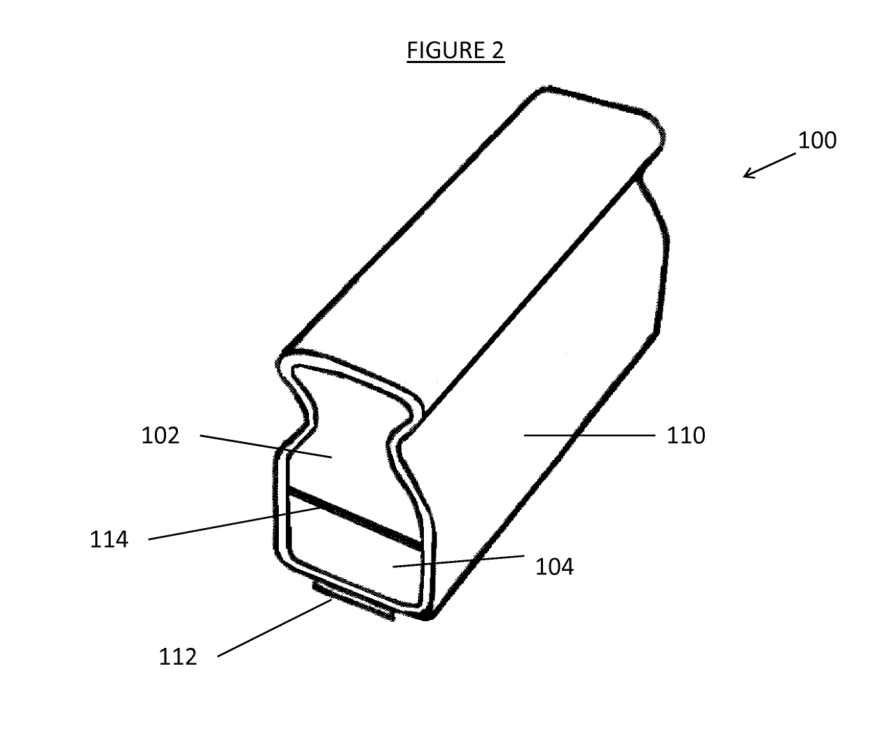

FIG. 2 shows a raised perspective view of the gasket 100. Here, the first and second foams 102, 104 are seen, as divided by an adhesive 114, having both been wrapped by an electrically conductive layer 110, and including a strip of pressure sensitive adhesive 112 thereunder.

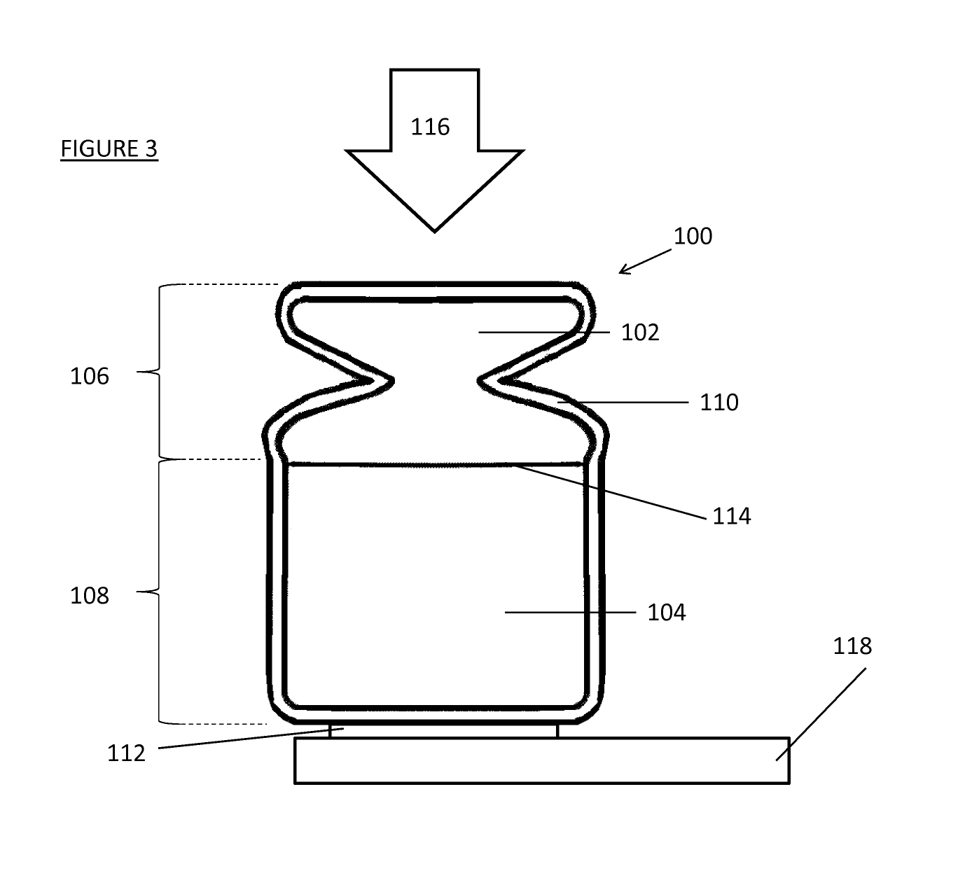

FIG. 3 shows the gasket of FIGS. 1 and 2, having undergone a partial compression from a downward force 116, the gasket having been adhered to a printed circuit board 118 via the pressure sensitive adhesive 112. In this embodiment, the first foam 102 includes a lower foam density than that of the second foam 104. This variation in density enables the first foam region 106 to compress under downward pressure before the second foam region 108 compresses.

In FIG. 3, the profile of the first foam 102 is that of an hourglass, as compared to the substantially rectangular profile of the second foam 104, thereby further enabling the first foam region 106 to compress from the downward force 116 before the second foam region 108 compresses. A variety of shapes may be used for the profile of the first foam 102 and/or the second foam 104, including those that might more easily compress, such as an hourglass shape as compared to a generally square shape. For example, the first foam 102 might be L-shaped, P-shaped, D-shaped, inverted T-shaped, rounded or square-bottomed U-shaped, V-shaped, or include any other suitable shape depending on the end use of the gasket, as long as the gasket contains at least two distinct regions of foam density.

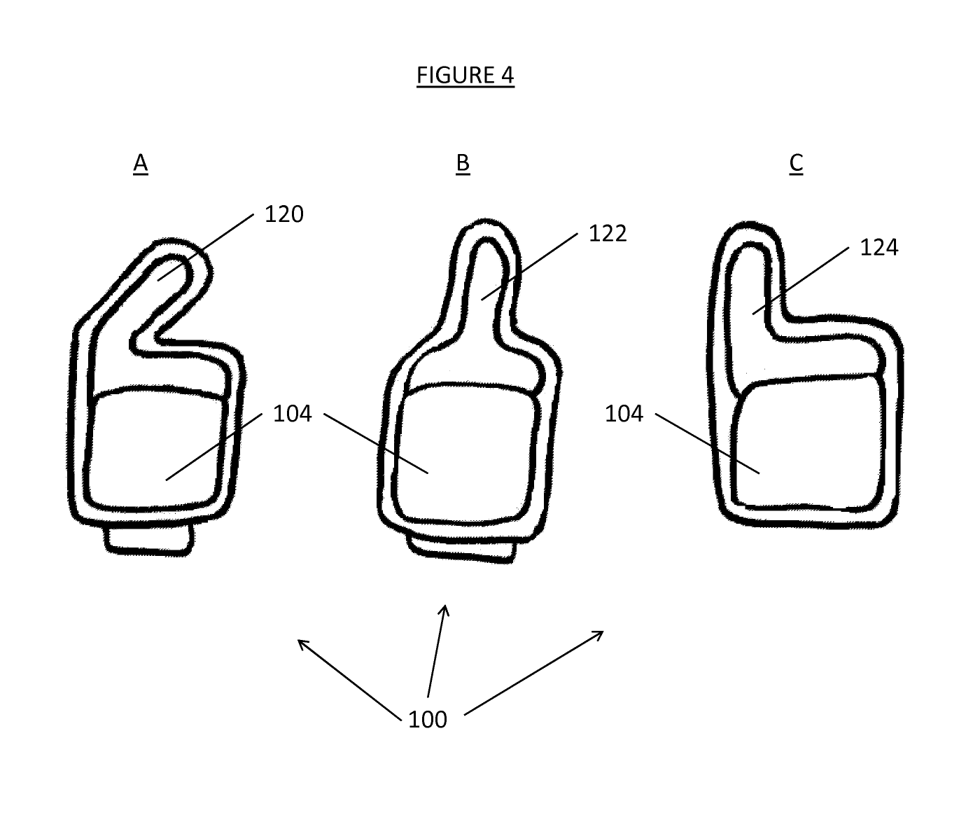

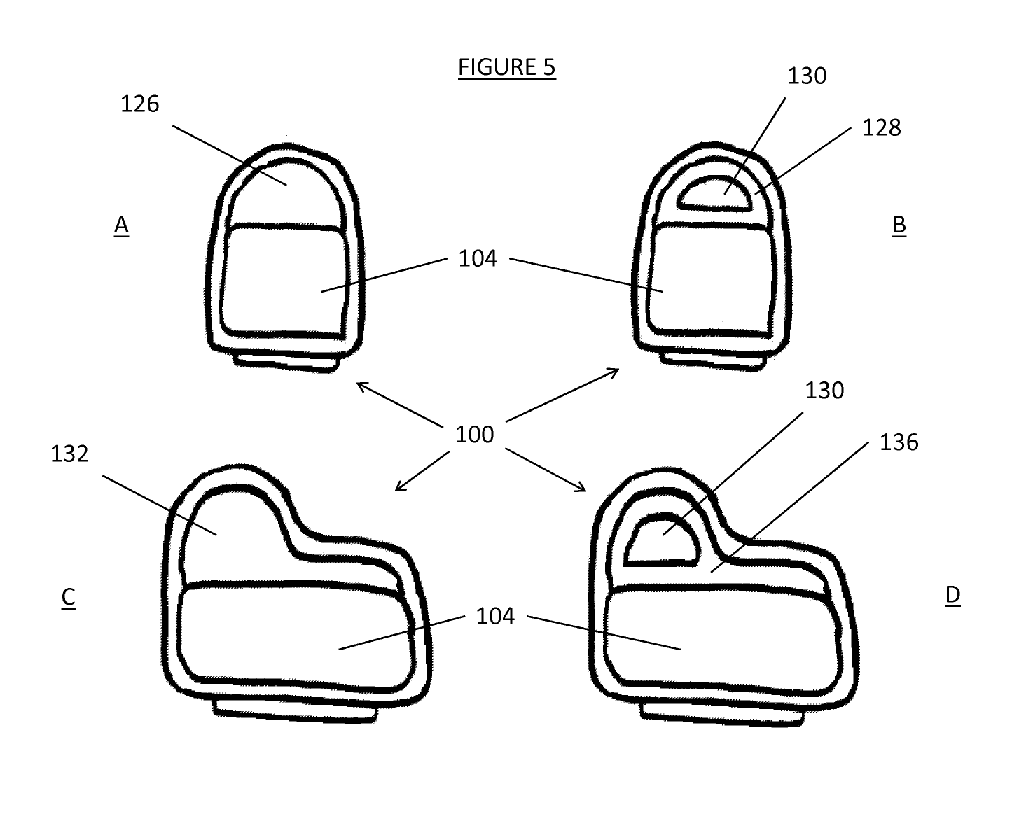

For example, FIG. 4A shows a gasket 100 having a square second foam 104 and a V-shaped first foam 120. Additionally, FIG. 4B shows a gasket having an inverted T-shaped first foam 122, while FIG. 4C includes a first foam having an L-shape 124. In some instances, as seen in FIG. 5, one foam may include a hollow region. Turning to FIG. 5A, the first foam is D-shaped 126, while FIG. 5B includes a hollow D-shaped first foam 128 with a hollow region 130 therein. Similarly, FIG. 5C shows a first foam having a P-shape 132 and a rectangular second foam 104, while FIG. 5D includes a hollow P-shaped first foam 136 having a hollow region therein. These and all other various profiles of first and second foams are embraced by this disclosure.

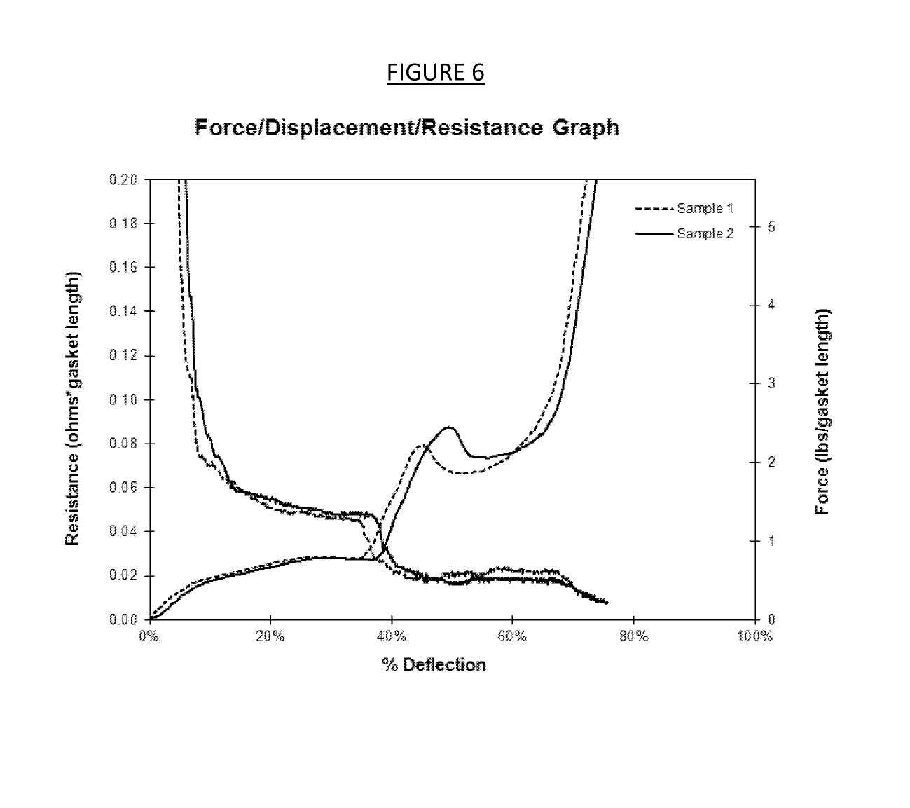

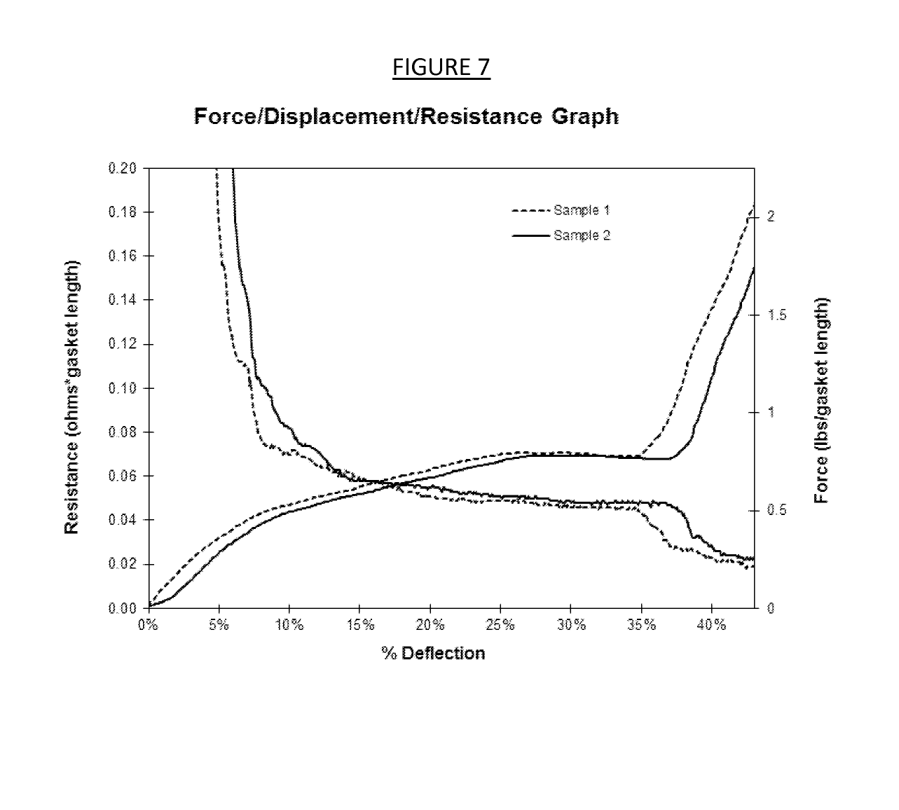

FIGS. 6 and 7 reflect Force/Displacement/Resistance data for a pair of samples of gaskets, this data being for gaskets having the profile and configuration seen in FIGS. 1 through 3. As can be seen in these tables, as the gasket deflects from a resting state (0% on the bottom left of the table in FIG. 4), the force required to deflect the gasket increases while the resistance of the gasket decreases. Noting the spike in force around 40% deflection, this represents a substantial compression of the first foam as seen in FIG. 3. The second foam, being of a higher density, requires another increase in applied force to deflect the second foam and thus the gasket as a whole. FIG. 5 represents similar data of the same two samples in the typical operating range of the gaskets of the disclosure, though any operation of the gasket as a conductive EMI gasket is embraced by this disclosure.

In an embodiment, the range of foam densities of any foam core in the gasket of the disclosure may be 2.5 pounds per foot cubed (lb/ft3) through 6 lb/ft3. In an embodiment, the density of the first foam may be 4 lb/ft3 as compared to a density in the second foam of 4.5 lb/ft3. While these examples are non-limiting, it should be noted that even a minor variation in foam density such as the aforementioned example is sufficient to achieve the benefits and performance described herein. The foam density variations can be complementarily paired with gasket profile shapes known in the art to promote deflection upon pressure relative to generally square shapes.

Gaskets of the disclosure are not limited to use as EMI attenuating components of electronics. Certain applications require the gaskets described herein to serve as grounding contacts for capacitive touch, electrostatic discharge, printed circuit board grounding, surface mount devices or other surface mount technologies. In those and other instances, the length of the gasket may not necessarily be longer than the width of the profile, for example. As used herein, the term “gasket” includes all such terms and uses. In the example of a surface mount device, it might be necessary for the base of the gasket to have a substantially square footprint. In this way, any gasket of any length having at least two distinct regions of foam density that are wrapped in conductive material are embraced by this disclosure, even those that are not serving primarily as EMI attenuating components.

To manufacture a gasket of the disclosure, certain elements of standard FOF EMI gasket manufacturing processes may be used.

In one typical FOF gasket manufacturing process, a single roll of foam is cut into substantially identical strips having generally rectangular profiles. Depending on the desired final profile view of the gasket, the subsequent steps vary. Where the profile view of the gasket is relatively similar to the profile of the foam strip, the strip may be wrapped with a conductive material, such as a metal-plated fabric, and adhered to the strip via hot melt adhesive. This wrapped strip may then be fed through a heated die that forms the gasket through pressure and heat into the desired final profile shape. A conductive pressure sensitive adhesive, for example, might also be attached to the base of the gasket, which may be cut to desired lengths. An example of such a profile may be an hourglass shape with relatively modest indentations. In some instances, where no reshaping of the gasket is necessary, it might still be fed through a heated die to press the conductive material snugly against the foam strip.

However, where the profile view of the gasket is distinct enough from a generally rectangular shape and/or where a heated die might fail to sufficiently form the gasket into the desired shape and/or where the foam might tend to spring back out of the desired shape, the foam strip may be die cut along its length into the desired final shape. After such die cutting, the cut foam strip may then be wrapped with the conductive material and adhered to the strip via hot melt adhesive. Optionally, a heated die may then press the conductive material snugly against the cut foam strip to create the final product, which can be cut to desired lengths. An example of such a profile may be an L-shaped shape with a relatively severe right angle indentation.

To manufacture a FOF EMI gasket of the disclosure, for example, the gasket seen in FIG. 1, where the first foam possesses a generally hourglass profile and the second foam possesses a generally rectangular or square profile with rounded corners, an embodiment of a new method of manufacture is needed. By way of non-limiting example, in such a process a roll of foam of a first density may be cut into strips of a certain width, and a roll of foam of a second density may be cut into strips of a certain width substantially equal to the width of the first density strips. In this embodiment, the first density is less than that of the second density. In this embodiment, the foam having a lesser density is machine fed alongside the foam having a higher density, while a double-sided adhesive is disposed therebetween such that the two foam strips are adhered together. In this embodiment, a conductive layer is wrapped around the two foam strips and adhered to the strips via a hot melt adhesive. This wrapped length of foams is then fed into a heated die that has a profile similar to the profile as seen in FIG. 1. This heated die seals the conductive layer to the foams and molds the foam of a lesser density into a generally hourglass shape, while the foam of a higher density retains its generally rectangular rounded edge shape. Optionally a strip of conductive pressure sensitive adhesive is affixed to the bottom of the gasket, along the conductive layer of the gasket adjacent to the foam of a higher density, distal from the foam of a lesser density. This method results in the gasket of FIG. 1.

While the aforementioned example method does not require die cutting in this embodiment, any suitable method of manufacture that results in a FOF EMI gasket having a plurality of distinct regions of foam densities is embraced by this disclosure. This may be achieved, for example, by die cutting the top lower density foam prior to adhering it to the bottom higher density foam, and then wrapping the foams with a conductive layer and hot melt adhesive and pushing the wrapped foam through a heated die.

In an embodiment, the FOF EMI gaskets of the disclosure may include an effective amount of flame retardant and be substantially free of halogen. Methods and manufactures of such gaskets are discussed in length in U.S. Pat. No. 7,060,348 and U.S. Pat. No. 8,545,974, both assigned to Laird Technologies, Inc. The entireties of those patents are hereby incorporated by reference as if fully restated herein.

Certain terminology is used herein for purposes of reference only, and thus is not intended to be limiting. For example, terms such as “upper”, “lower”, “above”, and “below” refer to directions in the drawings to which reference is made. Terms such as “front”, “back”, “rear”, “bottom” and “side”, describe the orientation of portions of the component within a consistent but arbitrary frame of reference which is made clear by reference to the text and the associated drawings describing the component under discussion. Such terminology may include the words specifically mentioned above, derivatives thereof, and words of similar import. Similarly, the terms “first”, “second” and other such numerical terms referring to structures do not imply a sequence or order unless clearly indicated by the context.

When introducing elements or features and the exemplary embodiments, the articles “a”, “an”, “the” and “said” are intended to mean that there are one or more of such elements or features. The terms “comprising”, “including” and “having” are intended to be inclusive and mean that there may be additional elements or features other than those specifically noted. It is further to be understood that the method steps, processes, and operations described herein are not to be construed as necessarily requiring their performance in the particular order discussed or illustrated, unless specifically identified as an order of performance. It is also to be understood that additional or alternative steps may be employed.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention as well as all equivalents thereof.

We claim:

1. A gasket comprising a foam core of indefinite length, the gasket having a profile, where the foam core is wrapped along its length in an electrically conductive layer adhered to the foam core via an adhesive layer therebetween;
wherein the foam core further comprises at least two distinct regions, wherein at least one region has a first foam density that is less than a second foam density of another region.

2. The gasket of claim 1, wherein the foam core is comprised of a first foam core having a first foam density and a second foam core having a second foam density.

3. The gasket of claim 2, wherein the first foam core and the second foam core are adhered together.

4. The gasket of claim 3, wherein the first foam core and the second foam core are adhered together with a double sided adhesive tape.

5. The gasket of claim 1, wherein the adhesive is a hot melt adhesive.

6. The gasket of claim 2, wherein the first foam density is less than the second foam density, and wherein the second foam core has a substantially rectangular profile shape, and wherein the first foam core has a profile shape selected from a group consisting of rectangular, hourglass, L-shaped, P-shaped, hollow P-shaped, D-shaped, hollow D-shaped, inverted T-shaped, rounded U-shaped, square-bottomed U-shaped, and V-shaped.

7. The gasket of claim 1 further comprising an adhesive strip, wherein the adhesive strip is affixed along the length of the gasket to the conductive layer, adjacent to the foam of a higher density, and distal from the foam of a lesser density.

8. The gasket of claim 7, wherein the adhesive strip is a conductive pressure sensitive adhesive.

9. The gasket of claim 1 wherein the foam core is comprised of a material selected from a group consisting of polyurethane foam, silicone foam, and conductive foam.

10. The gasket of claim 1, wherein the first foam density and the second foam density are both between 2.5 lb/ft³ and 6.0 lb/ft³.

11. The gasket of claim 10, wherein the first foam density is 4.0 lb/ft³ and the second foam density is 4.5 lb/ft³.

12. A gasket comprising at least two foam cores of equal yet indefinite length, the foam cores adhered to each other along their lengths and together wrapped in an electrically conductive layer adhered to the foam cores via an adhesive layer between the conductive layer and the foam cores, wherein a first foam core has a first foam density, and a second foam core has a second foam density that is greater than the first foam density.

13. The gasket of claim 12, wherein the first foam core and the second foam core are adhered together with a double sided adhesive tape.

14. The gasket of claim 12, wherein the first foam density is less than the second foam density, and wherein the second foam core has a substantially rectangular profile shape, and wherein the first foam core has a profile shape selected from a group consisting of L-shaped, P-shaped, hollow P-shaped, D-shaped, hollow D-shaped, inverted T-shaped, rounded U-shaped, square-bottomed U-shaped, and V-shaped.

15. The gasket of claim 12 further comprising an adhesive strip, wherein the adhesive strip is affixed along the length of the gasket to the conductive layer, adjacent to the foam of a higher density, and distal from the foam of a lesser density.

16. The gasket of claim 12, wherein the foam core is comprised of a material selected from a group consisting of polyurethane foam, silicone foam, and conductive foam.

17. The gasket of claim 12, wherein the first foam density and the second foam density are both between 2.5 lb/ft³and 6.0 lb/ft³.

18. The gasket of claim 17, wherein the first foam density is 4.0 lb/ft³ and the second foam density is 4.5 lb/ft³.

19. A gasket comprising a foam core of indefinite length, the gasket having a profile, where the foam core is wrapped along its length in an electrically conductive layer adhered to the foam core via a hot melt adhesive layer therebetween;
wherein the foam core further comprises at least two distinct regions, wherein at least one region has a first foam density that is less than a second foam density of another region;
wherein the second foam core has a substantially rectangular profile shape, and wherein the first foam core has a profile shape selected from a group consisting of rectangular, hourglass, L-shaped, P-shaped, hollow P-shaped, D-shaped, hollow D-shaped, inverted T-shaped, rounded U-shaped, square-bottomed U-shaped, and V-shaped;
the gasket further comprising a strip of pressure sensitive adhesive, wherein the strip is affixed along the length of the gasket to the conductive layer, adjacent to the foam of a higher density, and distal from the foam of a lesser density;
wherein the foam core is comprised of a material selected from a group consisting of polyurethane foam, silicone foam, and conductive foam;
wherein the conductive layer is selected from a group consisting of metallized film and metal plated fabric;
wherein the first foam density and the second foam density are both between 2.5 lb/ft³ and 6.0 lb/ft³.

20. The gasket of claim 19, wherein the first foam density is 4.0 lb/ft³ and the second foam density is 4.5 lb/ft³.

21. A method of manufacturing a gasket comprising the steps of: providing a first foam core of indefinite length, the first foam core having a first foam density; providing a second foam core of a length substantially equal to that of the first foam core, the second foam core having a second foam density; wherein the first foam density and the second foam density are of unequal values; adhering the first foam to the second foam core along their lengths, thereby creating a profile; and wrapping the first and second foam cores in a conductive layer.

22. The method of claim 21, wherein the adhering of the first foam core to the second foam core is achieved through the use of an adhesive material therebetween along the lengths of the cores, the adhesive material being selected from a group consisting of a double sided adhesive tape, a hot melt adhesive, and a pressure sensitive adhesive.

23. The method of claim 21, wherein the first foam core and the second foam core comprise material selected from a group consisting of polyurethane foam, silicone foam, and conductive foam.

24. The method of claim 21, wherein the first foam density and the second foam density are both between 2.5 lb/ft³and 6.0 lb/ft³.

25. The method of claim 24, wherein the first foam density is 4.0 lb/ft³ and the second foam density is 4.5 lb/ft³.
